(19) United States
(12) Patent Application Publication
(10) Pub. No.: US 2023/0403002 A1
(43) Pub. Date: Dec. 14, 2023

(54) SEMICONDUCTOR DEVICE

(71) Applicant: FUJI ELECTRIC CO., LTD., Kawasaki-shi (JP)

(72) Inventor: Masahiro TAOKA, Matsumoto-city (JP)

(73) Assignee: FUJI ELECTRIC CO., LTD., Kawasaki-shi (JP)

(21) Appl. No.: 18/322,084

(22) Filed: May 23, 2023

(30) Foreign Application Priority Data
Jun. 14, 2022 (JP) 2022-095619

(51) Int. Cl. H03K 17/082; H03K 5/24

(52) U.S. Cl. CPC H03K 17/0822; H03K 5/24

(57) ABSTRACT

An abnormal input control circuit includes at least one of a first, a second or a third detection circuit. The first detection circuit detects, as a first detection result, a noise superimposed on an input signal. The second detection circuit detects, as a second detection result, whether a pulse width of the input signal is less than or equal to a determined pulse width. The third detection circuit detects, as a third detection result, a mismatch between a level of the input signal and an operation of the switching element. An alarm and protection circuit includes an alarm signal output function and/or a drive adjustment function. Based on the first detection result, second detection result and/or the third detection result, the alarm and protection circuit outputs an alarm signal to outside by the alarm signal output function, and/or adjusts driving of the switching element by the drive adjustment function.

### CROSS-REFERENCE TO RELATED APPLICATION

This application is based upon and claims the benefit of priority of the prior Japanese Patent Application No. 2022-095619, filed on Jun. 14, 2022, the entire contents of which are incorporated herein by reference.

### BACKGROUND OF THE INVENTION

### 1. Field of the Invention

The embodiment discussed herein relates to a semiconductor device.

### 2. Background of the Related Art

In recent years, the development of a semiconductor device referred to as an intelligent power module (IPM) and incorporating a power semiconductor element, such as an insulated gate bipolar transistor (IGBT), a drive circuit which drives the power semiconductor element, and the like has progressed.

IPMs are widely used in vehicle electrical systems which supply power to, for example, a motor, an inverter, or a converter and the like. Products which comply with miniaturization, high performance, and high reliability are demanded.

Furthermore, an IPM has a monitoring and protection function for monitoring a current flowing through a power semiconductor element, the temperature of the power semiconductor element, or the like and protecting the power semiconductor element against breakage on the basis of a monitoring result.

For example, a technique for detecting whether the level of an input signal matches the level of a first delayed signal obtained by delaying the input signal with the maximum pulse width of noise as a delay amount and removing spike noise from the input signal is proposed as a related art (see, for example, International Publication Pamphlet No. WO 2008/044639). Furthermore, the following technique is proposed. An on signal pulse and an off signal pulse are generated from the rising and falling, respectively, of a high side input signal. The width of the off signal pulse is made longer than that of the on signal pulse. By doing so, a malfunction which occurs if the pulse width of the input signal becomes narrow is prevented (see, for example, Japanese Laid-open Patent Publication No. 2003-339151).

An IPM includes semiconductor chips including IGBTs and a control integrated circuit (IC) which drives the semiconductor chips and performs protection operations for the semiconductor chips. Furthermore, the control IC exercises drive control of the IGBTs included in the semiconductor chips on the basis of an input signal transmitted from the outside.

Conventional IPMs have a monitoring and protection function for overheat, overcurrent, and the like of a semiconductor chip, but do not have a monitoring and protection function for an abnormal input to a control IC.

As a result, for example, if high-frequency noise is superimposed on an input signal transmitted to a control IC or an input signal having a pulse width less than a determined pulse width is inputted to the control IC, then a malfunction of an IPM may occur.

Furthermore, if there is a mismatch between a level of an input signal and the operation of an IGBT, then a malfunction of an IPM may occur. In addition, a continuance of the malfunction of the IPM caused by such an abnormal input leads to breakage or a reduction in the life of an element.

### SUMMARY OF THE INVENTION

According to an aspect, there is provided a semiconductor device that receives an input signal, the semiconductor device including: a switching element; a drive circuit that performs a switching of the switching element using the input signal; and an abnormal input control circuit, including at least one of a first detection circuit that detects, as a first detection result, a noise superimposed on the input signal, a second detection circuit that detects, as a second detection result, whether a pulse width of the input signal is less than or equal to a determined pulse width, or a third detection circuit that detects, as a third detection result, a mismatch between a level of the input signal and an operation of the switching element, and an alarm and protection circuit, the alarm and protection circuit having at least one of an alarm signal output function or a drive adjustment function, based on the first detection result, the second detection result or the third direction result, the alarm signal output function outputting an alarm signal and the drive adjustment function adjusting a driving of the switching element.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 illustrates an example of the structure of a semiconductor device;

FIG. 3 is a functional block diagram of an abnormal input control circuit;

FIG. 4 is a time chart illustrative of a small pulse width detection operation; and

FIG. 5 is a time chart illustrative of a mismatch detection operation.

### DETAILED DESCRIPTION OF THE INVENTION

An embodiment will now be described with reference to the accompanying drawings.

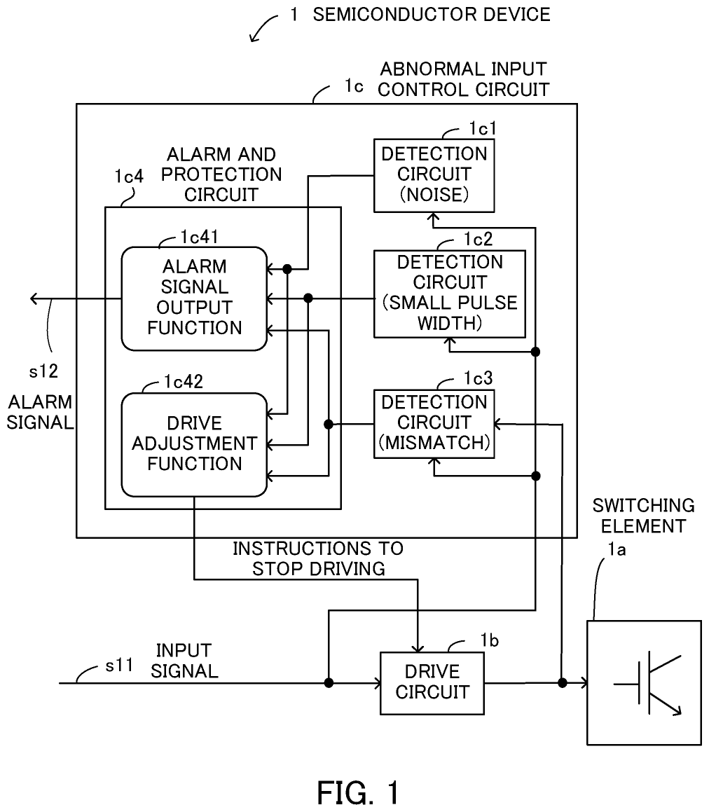

FIG. 1 is a view for describing an example of a semiconductor device. A semiconductor device 1 includes a switching element 1a, a drive circuit 1b, and an abnormal input control circuit 1c. The switching element 1a is a semiconductor element which turns on or off by drive control, and is a voltage-controlled semiconductor element such as an IGBT or a power metal-oxide-semiconductor field-effect transistor (MOSFET). The drive circuit 1b switching-drives the switching element 1a on the basis of an input signal s11.

The abnormal input control circuit 1c includes at least one of a detection circuit 1c1 (first detection circuit), a detection circuit 1c2 (second detection circuit), and a detection circuit 1c3 (third detection circuit). The detection circuit 1c1 detects noise superimposed on the input signal s11. The detection circuit 1c2 detects that a pulse width of the input signal s11 is less than or equal to a determined pulse width. The detection circuit 1c3 detects a mismatch between a level of the input signal s11 and the operation of the switching element 1a. The mismatch is an operation error that is detected by whether an ON or OFF operation of the switching element corresponds to a high or low level of the input signal.

Furthermore, the abnormal input control circuit 1c includes an alarm and protection circuit 1c4. The alarm and protection circuit 1c4 has at least one of an alarm signal output function 1c41 and a drive adjustment function 1c42. The alarm signal output function 1c41 outputs an alarm signal s12 to the outside on the basis of a detection result of at least one of the detection circuits 1c1, 1c2, and 1c3 to inform of an abnormal input state. In addition, the drive adjustment function 1c42 adjusts driving of the switching element 1a on the basis of a detection result of at least one of the detection circuits 1c1, 1c2, and 1c3.

As stated above, the semiconductor device 1 performs at least one of noise detection, small pulse width detection, and mismatch detection for the input signal s11 and performs at least one of outputting the alarm signal s12 and adjusting driving of the switching element 1a on the basis of a detection result. As a result, even if an abnormal input signal s11 is inputted, a malfunction is prevented.

<Structure of Semiconductor Device>

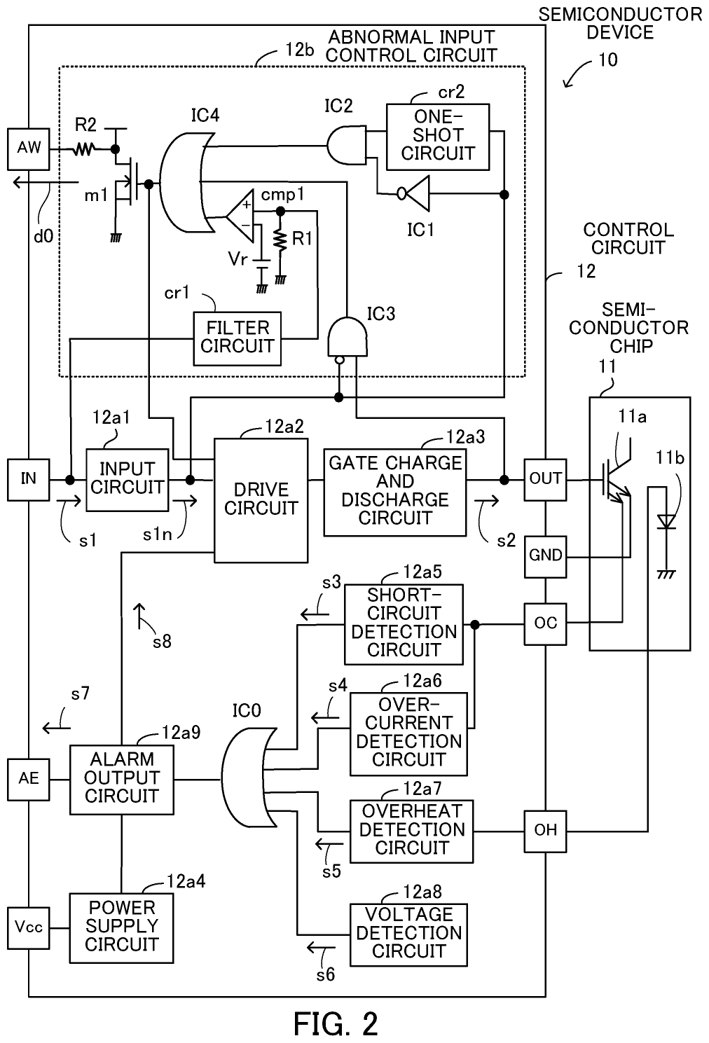

The structure of the semiconductor device 1 will now be described in further detail. FIG. 2 illustrates an example of the structure of a semiconductor device. A semiconductor device 10 is applied to, for example, an IPM and includes a semiconductor chip 11 and a control circuit 12 corresponding to a control IC.

The semiconductor chip 11 includes an IGBT 11a and a temperature detection diode 11b. The control circuit 12 includes as input-output terminals an input terminal IN, alarm output terminals AE and AW, a power supply terminal Vcc, an output terminal OUT, a ground terminal GND, an overcurrent detection terminal OC, and an overheat detection terminal OH.

Furthermore, the control circuit 12 includes an input circuit 12a1, a drive circuit 12a2, a gate charge and discharge circuit 12a3, a power supply circuit 12a4, a short-circuit detection circuit 12a5, an overcurrent detection circuit 12a6, an overheat detection circuit 12a7, a voltage detection circuit 12a8, an alarm output circuit 12a9, and an OR element IC0 with four inputs and one output. The input circuit 12a1, the drive circuit 12a2, and the gate charge and discharge circuit 12a3 realize the function of the drive circuit 1b illustrated in FIG. 1.

In addition, the control circuit 12 includes an abnormal input control circuit 12b. The abnormal input control circuit 12b includes a filter circuit cr1, a one-shot circuit cr2, an inverter element IC1, an AND element IC2 with two inputs and one output (logic element for small pulse width detection), an AND element IC3 with two inputs and one output (logic element for mismatch detection), an OR element IC4 with three inputs and one output, a comparator cmp1, resistors R1 and R2, and an NMOS transistor m1.

With the semiconductor chip 11, a gate of the IGBT 11a is connected to the output terminal OUT and an emitter of the IGBT 11a is connected to the ground terminal GND. A sense emitter of the IGBT 11a is connected to the overcurrent detection terminal OC. The semiconductor chip 11 includes a free wheeling diode (FWD) not illustrated and connected in inverse parallel with the IGBT 11a. Furthermore, an anode of the temperature detection diode 11b which detects the temperature of the IGBT 11a is connected to the overheat detection terminal OH and a cathode of the temperature detection diode 11b is connected to GND.

(Monitoring and Protection Function for the Semiconductor Chip 11)

An input signal s1 transmitted from a microcomputer or the like is inputted to an input terminal IN of the control circuit 12. If the control circuit 12 drives the IGBT 11a in a low-active state, then the input circuit 12a1 level-inverts the input signal s1 and outputs an inverted input signal s1n.

That is to say, when a gate level is at an H level, the IGBT 11a turns on. When a gate level is at an L level, the IGBT 11a turns off. Accordingly, if the control circuit 12 is in a low-active state, then an L-level input signal s1 is transmitted from the microcomputer to turn on the IGBT 11a. An H-level input signal s1 is transmitted from the microcomputer to turn off the IGBT 11a. As a result, the input circuit 12a1 inverts a level of the input signal s1 transmitted from the microcomputer and outputs the inverted input signal s1n to the next stage.

The drive circuit 12a2 generates a drive signal on the basis of the inverted input signal s1n outputted from the input circuit 12a1. On the basis of the drive signal, the gate charge and discharge circuit 12a3 outputs a gate charge and discharge signal s2 for charging the gate of the IGBT 11a to turn on the IGBT 11a or discharging the gate of the IGBT 11a to turn off the IGBT 11a. If the gate charge and discharge signal s2 is in an on state (at an H level), then the IGBT 11a is turned on. If the gate charge and discharge signal s2 is in an off state (at an L level), then the IGBT 11a is turned off.

The power supply circuit 12a4 converts a power supply voltage inputted from a power supply terminal Vcc to a control voltage for the control circuit 12 and applies it to each component. The short-circuit detection circuit 12a5 detects a short circuit for a load on the IGBT 11a on the basis of a sense current transmitted from the sense emitter of the IGBT 11a. If the short-circuit detection circuit 12a5 detects a short circuit, then the short-circuit detection circuit 12a5 outputs an H-level short-circuit detection signal s3.

When the overcurrent detection circuit 12a6 receives via the overcurrent detection terminal OC the sense current transmitted from the sense emitter of the IGBT 11a, the overcurrent detection circuit 12a6 converts the sense current to a sense voltage. Furthermore, the overcurrent detection circuit 12a6 compares the sense voltage with a predetermined current reference voltage. If the overcurrent detection circuit 12a6 determines on the basis of a comparison result that a current state of the IGBT 11a is an overcurrent state, then the overcurrent detection circuit 12a6 outputs an H-level overcurrent detection signal s4.

The overheat detection circuit 12a7 receives via the overheat detection terminal OH a temperature detection voltage transmitted from the temperature detection diode 11b. Furthermore, the overheat detection circuit 12a7 compares the temperature detection voltage with a predetermined temperature reference voltage. If the overheat detection circuit 12a7 detects on the basis of a comparison result that a temperature state of the IGBT 11a is an overheat state, then the overheat detection circuit 12a7 outputs an H-level overheat detection signal s5.

The voltage detection circuit 12a8 detects whether or not the control voltage generated by the power supply circuit 12a4 is higher than or equal to a predetermined threshold voltage. If the voltage detection circuit 12a8 detects that the control voltage is lower than the predetermined threshold voltage, then the voltage detection circuit 12a8 outputs an H-level voltage drop detection signal s6.

The short-circuit detection signal s3, the overcurrent detection signal s4, the overheat detection signal s5, and the voltage drop detection signal s6 are inputted to input ends of the OR element IC0. Accordingly, if at least one abnormal state of a short-circuit state, an overcurrent state, an overheat state, and a control voltage drop state arises, then the OR element IC0 outputs an H-level signal.

When the alarm output circuit 12a9 receives the H-level signal from the OR element IC0, the alarm output circuit 12a9 generates an alarm signal s7 and outputs it via the alarm output terminal AE. Furthermore, the alarm output circuit 12a9 informs the outside that at least one of a short-circuit state, an overcurrent state, an overheat state, and a control voltage drop state has arisen. The power supply circuit 12a4 has the function of performing power-on reset when the alarm signal s7 is outputted.

In addition, when the alarm output circuit 12a9 receives the H-level signal from the OR element IC0, the alarm output circuit 12a9 outputs a drive adjustment signal s8 to the drive circuit 12a2. When the drive circuit 12a2 receives the drive adjustment signal s8, the drive circuit 12a2 gives the gate charge and discharge circuit 12a3 instructions to discharge the gate of the IGBT 11a. By doing so, the IGBT 11a is turned off and driving of the IGBT 11a is adjusted.

(Monitoring and Protection Function for an Abnormal Input)

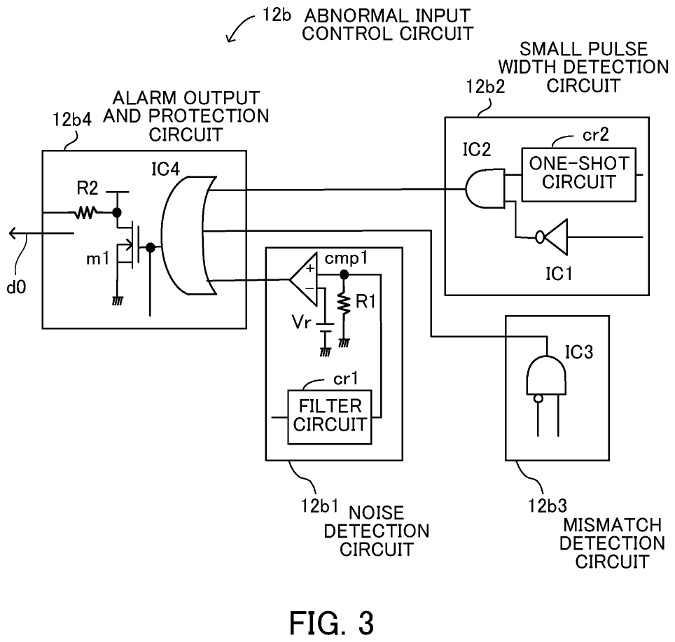

A monitoring and protection function for an abnormal input performed by the control circuit 12 will now be described with reference to FIG. 2 and FIG. 3. FIG. 3 is a functional block diagram of the abnormal input control circuit. FIG. 3 illustrates the structure of the functional blocks of the abnormal input control circuit 12b illustrated in FIG. 2. The abnormal input control circuit 12b which performs monitoring and protection for an abnormal state of the input signal s1 includes a noise detection circuit 12b1, a small pulse width detection circuit 12b2, a mismatch detection circuit 12b3, and an alarm output and protection circuit 12b4.

(Noise Detection Circuit)

The noise detection circuit 12b1 has the function of the detection circuit 1c1 illustrated in FIG. 1. The noise detection circuit 12b1 includes the filter circuit cr1, the comparator cmp1, and the resistor R1. The input signal s1 is inputted to an input end of the filter circuit cr1. An output end of the filter circuit cr1 is connected to a non-inverting input terminal (+) of the comparator cmp1 and one end of the resistor R1. The other end of the resistor R1 is connected to the GND. A reference voltage Vr is inputted to an inverting input terminal (−) of the comparator cmp1. An output end of the comparator cmp1 is connected to one input end of the three inputs of the OR element IC4.

The noise detection circuit 12b1 detects high-frequency noise superimposed on the input signal s1 inputted to the input terminal IN of the control circuit 12. The filter circuit cr1 which performs high-pass filtering is located in parallel with a line through which the input signal s1 flows. The high-frequency noise superimposed on the input signal s1 is extracted and induced by the filter circuit cr1 and is outputted from the filter circuit cr1.

Because the pull-down resistor R1 is connected to the output end of the filter circuit cr1, a voltage signal corresponding to a high-frequency noise component is inputted to the non-inverting input terminal (+) of the comparator cmp1. Furthermore, the comparator cmp1 compares the voltage signal corresponding to the high-frequency noise component with the reference voltage Vr. If the voltage signal is higher than or equal to the reference voltage Vr, then the comparator cmp1 outputs an H-level signal (noise detection signal). By adopting the above structure, the high-frequency noise superimposed on the input signal s1 is detected.

As stated above, if high-frequency noise is superimposed on the input signal s1, then noise having frequencies higher than and equal to a cut-off frequency flows to the filter circuit cr1 in the noise detection circuit 12b1. Because the pull-down resistor R1 is connected to the output end of the filter circuit cr1, a voltage across the resistor R1 is inputted to the non-inverting input terminal (+) of the comparator cmp1. When a voltage inputted to the non-inverting input terminal (+) of the comparator cmp1 becomes higher than or equal to the reference voltage Vr, the comparator cmp1 outputs an H-level signal for putting an alarm function into an on state.

Because the filtering capability of the filter circuit cr1, the resistance value of the resistor R1, or the value of the reference voltage Vr is adjustable, detection control is flexibly exercised according to the frequency or voltage width of noise superimposed on the input signal s1.

(Small Pulse Width Detection Circuit)

The small pulse width detection circuit 12b2 has the function of the detection circuit 1c2 illustrated in FIG. 1. The small pulse width detection circuit 12b2 includes the inverter element IC1, the one-shot circuit cr2, and the AND element IC2.

The inverted input signal s1n obtained by level inversion performed by the input circuit 12a1 is inputted to an input end of the inverter element IC1. An output end of the inverter element IC1 is connected to one input end of the AND element IC2. The inverted input signal s1n obtained by level inversion performed by the input circuit 12a1 is inputted to an input end of the one-shot circuit cr2. An output end of the one-shot circuit cr2 is connected to the other input end of the AND element IC2. An output end of the AND element IC2 is connected to one input end of the three inputs of the OR element IC4.

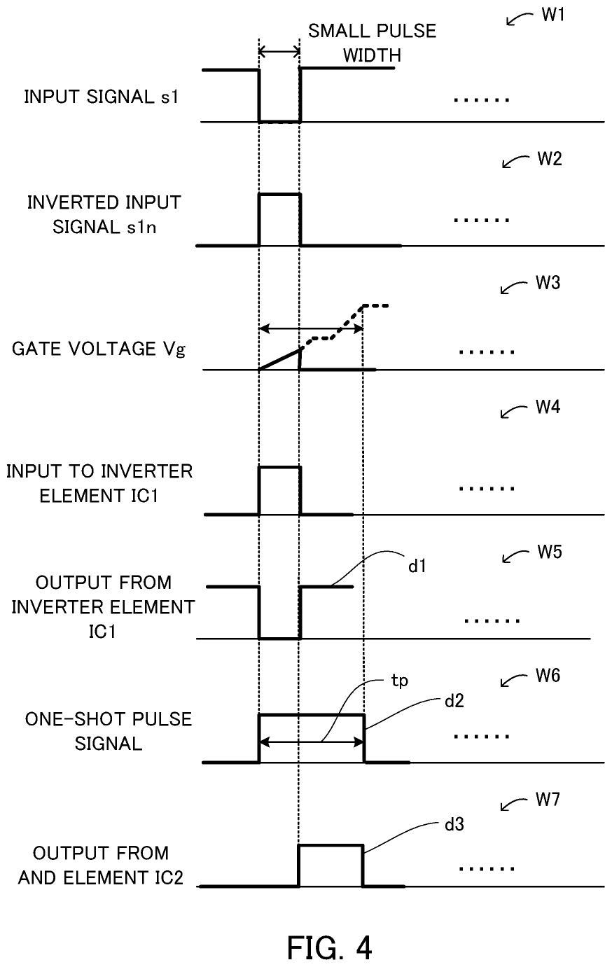

The small pulse width detection circuit 12b2 detects that the input signal s1 is in a small pulse width state. The one-shot circuit cr2 outputs a one-shot pulse signal having a determined pulse width at the same time when the input circuit 12a1 outputs the inverted input signal s1n. Furthermore, if a pulse width of the inverted input signal s1n is less than or equal to the pulse width of the one-shot pulse signal, then a pulse width of the input signal s1 is detected as a small pulse width (details will be described later in FIG. 4).

(Mismatch Detection Circuit)

The mismatch detection circuit 12b3 has the function of the detection circuit 1c3 illustrated in FIG. 1. The mismatch detection circuit 12b3 includes the AND element IC3. The inverted input signal s1n obtained by level inversion performed by the input circuit 12a1 is inputted to an inverting input terminal of the AND element IC3. The gate charge and discharge signal s2 outputted from the gate charge and discharge circuit 12a3 is inputted to a non-inverting input terminal of the AND element IC3. An output end of the AND element IC3 is connected to one input end of the three inputs of the OR element IC4.

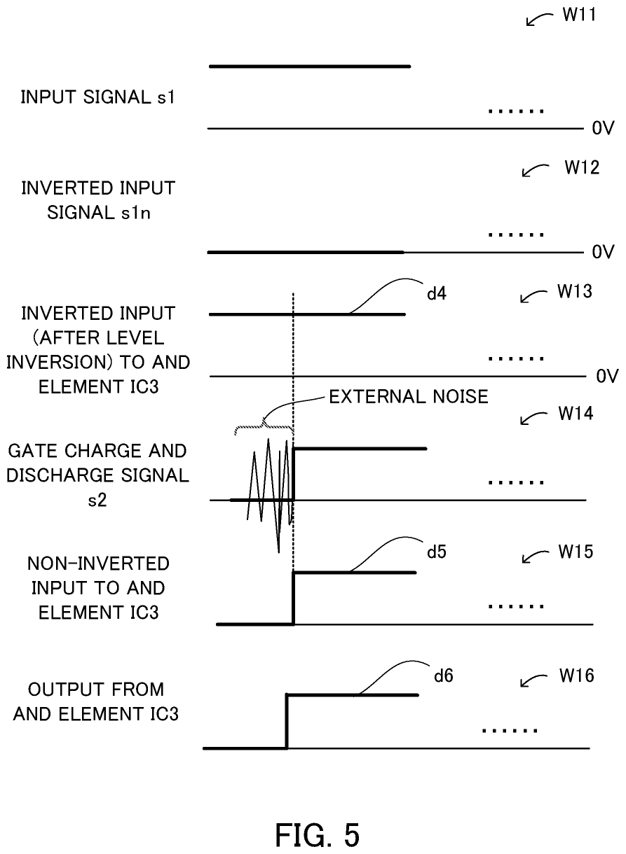

For example, when the input signal s1 is at an H level, the AND element IC3 of the mismatch detection circuit 12b3 determines whether or not the gate charge and discharge signal s2 is in an off state. By doing so, the mismatch detection circuit 12b3 detects a mismatch between a level of the input signal s1 and an operation of the IGBT 11a (details will be described later in FIG. 5).

The control circuit 12 is in a low-active state. Accordingly, when the input signal s1 is at an H level, instructions to turn off the IGBT 11a are given. As a result, if the gate charge and discharge signal s2 is in an off state (instructions to turn off the IGBT 11a are given) when the input signal s1 is at an H level, then a level of the input signal s1 matches an operation of the IGBT 11a. If the gate charge and discharge signal s2 is in an on state (instructions to turn on the IGBT 11a are given) when the input signal s1 is at an H level, then there is a mismatch between a level of the input signal s1 and an operation of the IGBT 11a.

(Alarm Output and Protection Circuit)

The alarm output and protection circuit 12b4 has the function of the alarm and protection circuit 1c4 illustrated in FIG. 1. The alarm output and protection circuit 12b4 includes the OR element IC4, the resistor R2, and the NMOS transistor m1. The output end of the comparator cmp1, the output end of the AND element IC2, and the output end of the AND element IC3 are connected to the three input ends of the OR element IC4.

An output end of the OR element IC4 is connected to a gate of the NMOS transistor m1 and an input end of the drive circuit 12a2. A drain of the NMOS transistor m1 is connected to a power source voltage and one end of the resistor R2. A source of the NMOS transistor m1 is connected to the GND. The other end of the resistor R2 is connected to the alarm output terminal AW.

If at least one abnormal state of a state in which noise is superimposed, a small pulse width state, and a mismatch state arises, then the OR element IC4 outputs an H-level signal. Because the power source voltage is applied to the drain of the NMOS transistor m1 and the source of the NMOS transistor m1 is connected to the GND, the NMOS transistor m1 is turned on when the H-level signal is inputted to the gate of the NMOS transistor m1.

When the NMOS transistor m1 is turned on, an L-level alarm signal d0 (alarm signal) is outputted from the alarm output terminal AW via the resistor R2 connected to the drain of the NMOS transistor m1 (alarm signal d0 at an L level indicates an abnormal input state).

Furthermore, an output of the OR element IC4 is also inputted to the drive circuit 12a2. When the drive circuit 12a2 receives the H-level signal from the OR element IC4, the drive circuit 12a2 gives the gate charge and discharge circuit 12a3 instructions to discharge the gate of the IGBT 11a. By doing so, the IGBT 11a is turned off and driving of the IGBT 11a is adjusted. That is to say, the H-level signal outputted from the OR element IC4 also functions as a drive adjustment signal for the IGBT 11a. As a result, the function of protection against an abnormal input is realized.

(Small Pulse Width Detection Operation)

FIG. 4 is a time chart illustrative of a small pulse width detection operation.

(Waveform W1) An L-level input signal s1 is inputted to the input terminal IN of the control circuit 12. Because the control circuit 12 is in a low-active state, the L-level input signal s1 means instructions to turn on the IGBT 11a. It is assumed that an abnormal input signal s1 having a pulse width (second pulse width by which charging the gate of the IGBT 11a is not normally completed) less than a pulse width needed to normally complete charging the gate of the IGBT 11a.

(Waveform W2) The input circuit 12a1 inverts the input signal s1 and outputs an H-level inverted input signal s1n.

(Waveform W3) The drive circuit 12a2 generates a drive signal on the basis of the inverted input signal s1n. The gate charge and discharge circuit 12a3 charges the gate of the IGBT 11a on the basis of the drive signal. However, the gate of the IGBT 11a is charged on the basis of the input signal s1 having a small pulse width. As a result, a gate voltage Vg of the IGBT 11a does not rise to a determined voltage value.

(Waveform W4) The inverted input signal s1n is inputted to the inverter element IC1.

(Waveform W5) The inverter element IC1 inverts the level of the inverted input signal s1n and outputs an L-level pulse signal d1.

(Waveform W6) The one-shot circuit cr2 outputs an H-level one-shot pulse signal d2 at the same time when the inverted input signal s1n is inputted. A pulse width tp (first pulse width) of the one-shot pulse signal d2 has a time width by which charging the gate of the IGBT 11a is normally completed. That is to say, the pulse width tp has a time width from the time when the inverted input signal s1n is inputted to the one-shot circuit cr2 to the time when charging the gate of the IGBT 11a is normally completed.

(Waveform W7) The AND element IC2 ANDs the L-level pulse signal d1 and the one-shot pulse signal d2 and outputs an H-level signal d3 (small pulse width detection signal). When the H-level signal d3 is outputted from the AND element IC2, it is detected that the input signal s1 is in a small pulse width state (input signal s1 having a pulse width which is too small to turn on the IGBT 11a is inputted to the control circuit 12). At this time, an L-level alarm signal d0 is outputted from the alarm output terminal AW.

As stated above, when the input signal s1 is inputted to the control circuit 12, the one-shot circuit cr2 which outputs a one-shot pulse signal having a determined pulse width starts. If the input signal s1 goes into an off state before the pulse width of the one-shot pulse signal elapses, then two inputs to the AND element IC2 are at an H level. As a result, an H-level signal is outputted from the AND element IC2 for putting an alarm function into an on state.

(Mismatch Detection Operation)

FIG. 5 is a time chart illustrative of a mismatch detection operation.

(Waveform W11) An H-level input signal s1 is inputted to the input terminal IN of the control circuit 12. Because the control circuit 12 is in a low-active state, the H-level input signal s1 means instructions to turn off the IGBT 11a.

(Waveform W12) The input circuit 12a1 inverts the input signal s1 and outputs an L-level inverted input signal s1n.

(Waveform W13) The inverted input signal s1n is inputted to the inverting input terminal of the AND element IC3. Waveform W13 indicates an input waveform (H-level signal d4) to the AND element IC3 obtained by level-inverting the inverted input signal s1n.

(Waveform W14) It is assumed that the gate charge and discharge circuit 12a3 is malfunctioning. Because the input signal s1 is at an H level (inverted input signal s1n is at an L level), the gate charge and discharge circuit 12a3 outputs an L-level gate charge and discharge signal s2 in itself to discharge the gate of the IGBT 11a. In reality, however, the gate charge and discharge circuit 12a3 outputs an H-level signal. For example, such a malfunction may occur by the influence of external noise produced by a device, such as an external transceiver, which outputs powerful electromagnetic waves or a switch of a high-voltage apparatus.

(Waveform W15) Because the gate charge and discharge signal s2 outputted from the gate charge and discharge circuit 12a3 is at an H level, an H-level signal d5 is inputted to the non-inverting input terminal of the AND element IC3.

(Waveform W16) The AND element IC3 ANDs the H-level signal d4 and the H-level signal d5 and outputs an H-level signal d6 (mismatch detection signal). When the H-level signal d6 is outputted from the AND element IC3, it is detected that there is a mismatch between the level of the input signal s1 and the operation of the IGBT 11a. At this time, an L-level alarm signal d0 is outputted from the alarm output terminal AW.

As stated above, if there is a mismatch between a level of the inverted input signal s1n and a level of the gate charge and discharge signal s2, then an H-level signal is outputted from the AND element IC3 for putting an alarm function into an on state.

As has been described, according to the present disclosure, noise superimposed on an input signal inputted to the control circuit of the semiconductor device, the input signal having an improper pulse width, or a mismatch between a level of the input signal and an operation of the IGBT is detected, then, notice is given to the outside at the time of detecting an abnormal state, and driving of the IGBT is adjusted at the time of detecting the abnormal state. This efficiently prevents a malfunction caused by an abnormal input. Furthermore, the abnormal input is elucidated or the element is protected.

The embodiment has been taken as an example. The structure of each section indicated in the embodiment may be replaced by another structure having the same function. Furthermore, any other component or process may be added. Moreover, the structures (features) of any two or more of the above embodiments may be combined.

According to an aspect, an abnormal input is detected and a malfunction is prevented.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device that receives an input signal, the semiconductor device comprising:
a switching element;
a drive circuit that performs a switching of the switching element using the input signal; and
an abnormal input control circuit, including
at least one of a first detection circuit that detects, as a first detection result, a noise superimposed on the input signal, a second detection circuit that detects, as a second detection result, whether a pulse width of the input signal is less than or equal to a determined pulse width, or a third detection circuit that detects, as a third detection result, a mismatch between a level of the input signal and an operation of the switching element, and
an alarm and protection circuit, the alarm and protection circuit having at least one of an alarm signal output function or a drive adjustment function, based on the first detection result, the second detection result or the third direction result, the alarm signal output function outputting an alarm signal and the drive adjustment function adjusting a driving of the switching element.

2. The semiconductor device according to claim 1, wherein:
the first detection circuit includes a filter circuit, a resistor, and a comparator;
the filter circuit includes an input end that receives the input signal and an output end that is connected to both a non-inverting input terminal of the comparator and one end of the resistor, an other end of the resistor being connected to a ground, the comparator including an inverting input terminal that receives a reference voltage; and
the filter circuit filters and outputs the noise superimposed on the input signal, the comparator compares a voltage signal of the noise with the reference voltage, and outputs, in response to a detection that the voltage signal is higher than or equal to the reference voltage, a noise detection signal as the first detection result, the noise detection signal being indicative that the noise is superimposed on the input signal.

3. The semiconductor device according to claim 1, wherein:
the drive circuit generates an inverted input signal by level-inverting the input signal and drives the switching element using the inverted input signal;
the second detection circuit includes an inverter element, a one-shot circuit, and a small pulse width detection logic element;
the inverter element includes an input end that receives the inverted input signal and an output end that is connected to one input end of the small pulse width detection logic element, the one-shot circuit including an input end that receives the inverted input signal and an output end that is connected to an other input end of the small pulse width detection logic element;
the one-shot circuit outputs a one-shot pulse signal having a determined first pulse width to the small pulse width detection logic element in response to receipt of the inverted input signal; and
the small pulse width detection logic element outputs, in response to a detection that a second pulse width of a pulse signal outputted from the inverter element is less than the first pulse width of the one-shot pulse signal, a small pulse width detection signal as the second detection result, the small pulse width detection signal being indicative that the pulse width of the input signal is less than or equal to the determined pulse width.

4. The semiconductor device according to claim 3, wherein the first pulse width has a time width from a time when the inverted input signal is inputted to the one-shot circuit to a time when a charging of a gate of the switching element is completed.

5. The semiconductor device according to claim 1, wherein:
the drive circuit generates an inverted input signal by level-inverting the input signal, generates a gate charge and discharge signal using the inverted input signal, for charging and discharging a gate of the switching element, and drives the switching element;
the third detection circuit includes a mismatch detection logic element having an inverting input terminal that receives the inverted input signal, and a non-inverting input terminal that receives the gate charge and discharge signal; and
in response to a detection of a mismatch between a level of the inverted input signal and a level of the gate charge and discharge signal, the mismatch detection logic element outputs a mismatch detection signal as the third detection result, the mismatch detection signal being indicative that the mismatch exists.

6. The semiconductor device according to claim 1, wherein the abnormal input control circuit outputs the alarm signal using the alarm signal output function, in response to at least one of a detection of the noise by the first detection circuit, a detection of the pulse width by the second detection circuit that is less than or equal to the determined pulse width, or a detection of the mismatch by the third detection circuit.

7. The semiconductor device according to claim 1, wherein the abnormal input control circuit adjusts the driving of the switching element using the drive adjustment function, in response to at least one of a detection of the noise by the first detection circuit, a detection of the pulse width that is less than or equal to the determined pulse width, or a detection of the mismatch by the third detection circuit.
